(19) United States
(12) Patent Application Publication
(10) Pub. No.: US 2011/0051113 A1
(43) Pub. Date: Mar. 3, 2011

(54) LITHOGRAPHY SYSTEM AND OPTICAL MODULE THEREOF

(76) Inventor: Wei-Cheng Shiu, Taoyuan County (TW)

(21) Appl. No.: 12/551,572

(22) Filed: Sep. 1, 2009

(51) Int. Cl. G03F 7/20; G03B 27/52

(52) U.S. Cl. 355/71; 355/67

(57) ABSTRACT

A lithography system includes a light source, a photo mask positioned downstream of the light source, an optical module having a front surface positioned downstream of the photo mask, and a wafer stage positioned downstream of the optical module for supporting a wafer, wherein the wafer comprises a dry film and a first medium positioned between the front surface of the optical module and a surface of the dry film. The optical module includes a container, a liquid medium situated in the container and a first set of lenses immersed in the liquid medium.

### BACKGROUND OF THE INVENTION

1. Field of the Invention

The present invention relates generally to the field of integrated circuit manufacturing and, more particularly, to a lithography system with lenses immersed in a liquid medium.

2. Description of the Prior Art

The manufacture of integrated circuits requires multiple photolithographic steps to define and create specific circuit features and components layer-by-layer onto a semiconductor wafer.

For instance, patterns can be formed from a photo resist layer disposed on the wafer by passing light energy through a mask having an arrangement in order to image the desired pattern onto the photo resist layer. As a result, a latent pattern is transferred to the photo resist layer. In areas where the photo resist layer is sufficiently exposed, after a development cycle, the photo resist layer can become soluble such that it can be removed to selectively expose an underlying layer (e.g., a semiconductor layer, a metal or metal containing layer, a dielectric layer, a hard mask layer, etc.). Portions of the photo resist layer not exposed to a threshold amount of light energy will not be removed and serve to protect the underlying layer during further processing of the wafer. Afterwards, the remaining portions of the photo resist layer will be removed.

There is a pervasive trend in the art of IC fabrication to increase the density with which various structures are arranged. As a result, there is a corresponding need to increase the resolution of lithography systems.

A conventional method for improving resolution includes the methods of: off-axis illumination, immersion lithography and increasing the numerical aperture of the lens. In addition, some methods involve adjusting equipment parameters, such as adapting exposure energy and exposure time in order to achieve a better resolution and achieve a compromise between resolution and depth of focus. However, satisfactory results have not yet been obtained.

Therefore, it is important to develop a lithography system with improved resolution that has compatibility with current equipment.

### SUMMARY OF THE INVENTION

The following presents a simplified summary of the invention in order to provide a basic understanding of some aspects of the invention. This summary is not an extensive overview of the invention. It is intended to neither identify key or critical elements of the invention nor delineate the scope of the invention. Its purpose is merely to present some concepts of the invention in a simplified form as a prelude to the more detailed description that is presented later.

According to a preferred embodiment of the invention, an optical module of a lithography system comprises: a container; a liquid medium positioned within the container; and a first set of lenses immersed in the liquid medium.

According to another preferred embodiment of the invention, a lithography system comprises: a light source; a photo mask positioned downstream of the light source; and an optical module having a front surface positioned downstream of the photo mask, wherein the optical module comprises: a container; a liquid medium situated in the container; and a first set of lenses immersed in the liquid medium. The lithography system further comprises: a wafer stage positioned downstream of the optical module for supporting a wafer, wherein the wafer comprises a dry film; and a first medium positioned between the front surface of the optical module and a surface of the dry film.

A feature of the present invention is that the lenses in the optical module of the lithography system are immersed in the liquid medium to thereby improve the numerical aperture.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a schematic diagram of a lithography system according to a preferred embodiment of the present invention.

FIG. 2 is a magnified localized view of the second lens module shown in FIG. 1 according to the first embodiment of the present invention.

FIG. 3 is a magnified localized view of the second lens module shown in FIG. 1 according to a second embodiment of the present invention.

### DETAILED DESCRIPTION

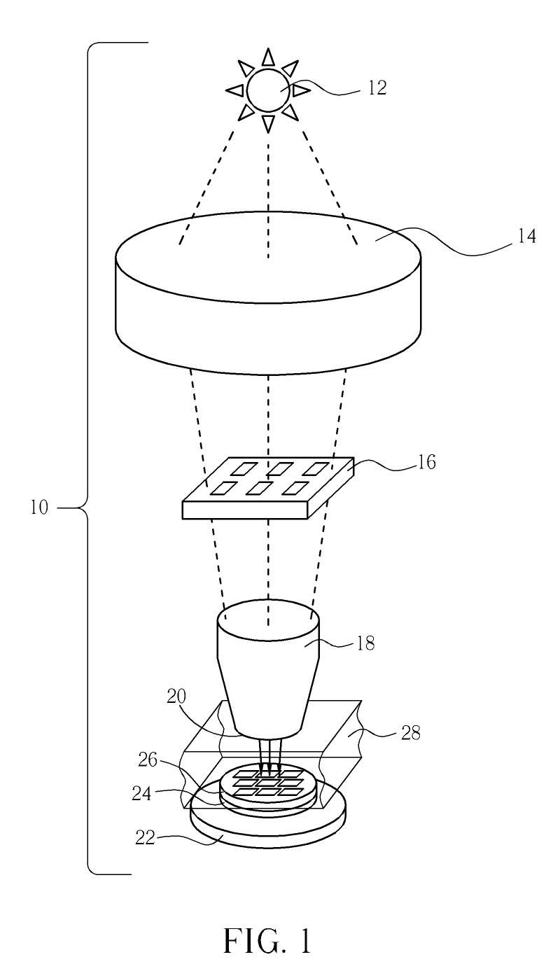

FIG. 1 depicts a schematic diagram of a lithography system 10 according to a preferred embodiment of the present invention. As shown in FIG. 1, a lithography system 10 includes: a light source 12, a first lens module 14 positioned downstream of the light source 12, a photo mask 16 positioned downstream of the first lens module 14, a second lens module 18 having a front surface 20 facing away from the photo mask 16, and a wafer stage 22 positioned downstream of the second lens module 18 for supporting a wafer 24, wherein the wafer 24 includes a dry film 26. In addition, there is a medium 28 disposed between the front surface 20 and the top surface of the dry film 26.

The light source 12 can have, for example, a deep ultraviolet wavelength (e.g., about 248 nm or about 193 nm), or a vacuum ultraviolet (VUV) wavelength (e.g., about 157 nm), although other wavelengths (e.g., an extreme ultraviolet wavelength) are possible and are also considered to fall within the scope of the invention described and claimed herein. The photo mask 16 selectively blocks light source 12 such that a pattern defined by the photo mask 16 is transferred towards the dry film 26.

The medium 28 may be air. According to a preferred embodiment of the present invention, the medium 28 may be a liquid, a supercritical fluid, or other medium having a refractive index that is greater than 1.4 at a wavelength of 193 nm.

It is noteworthy that the second lens module 18 of the present invention has a special design to increase the resolution of the lithography system 10.

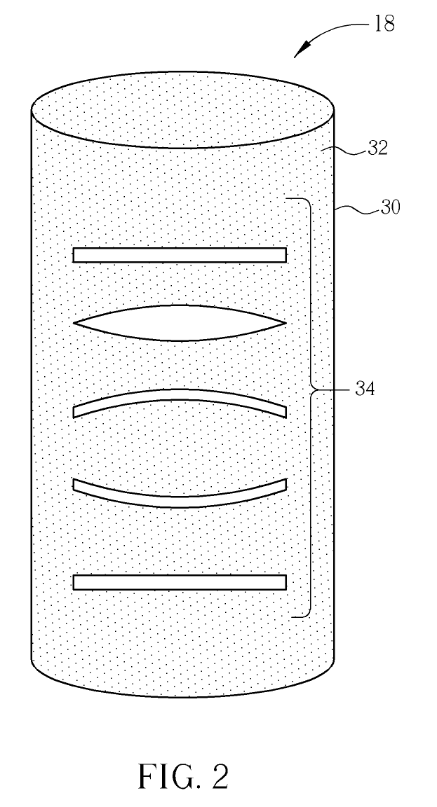

FIG. 2 is a magnified localized view of the second lens module 18 shown in FIG. 1 according to the first embodiment of the present invention. As shown in FIG. 2, the second lens module 18 includes a container 30, a liquid medium 32 within the container 30 and a set of lenses 34 immersed in the liquid medium 32. The shape of the container 30 may be cylindrical or other shapes. The shape of the container 30 given in FIG. 2 is for illustrative purposes only.

The liquid medium 32 may be de-ionized water, a mixture of phosphoric acid (H₃PO₄) and water, a phosphoric acid solution, “Delphi”, which is available from Mitsui Chemical, oil (e.g., perfluorinated polyethers (PFPE)) or other liquids having a refractive index that is greater than 1.4 at a wavelength of 193 nm. The refractive index of the liquid medium 32 corresponds to the refractive index of the set of lenses 34, such that the refractive index of the liquid medium 32 matches or approaches the refractive index of the set of lenses 34. The refractive index of the liquid medium 32 depends on the refractive index of the whole lithography system including lenses, the photo resist, and other mediums. The refractive index of the liquid medium 32 can be any value which matches the refractive indices of the whole lithography system. Moreover, the liquid medium 32 may be identical to the medium 28.

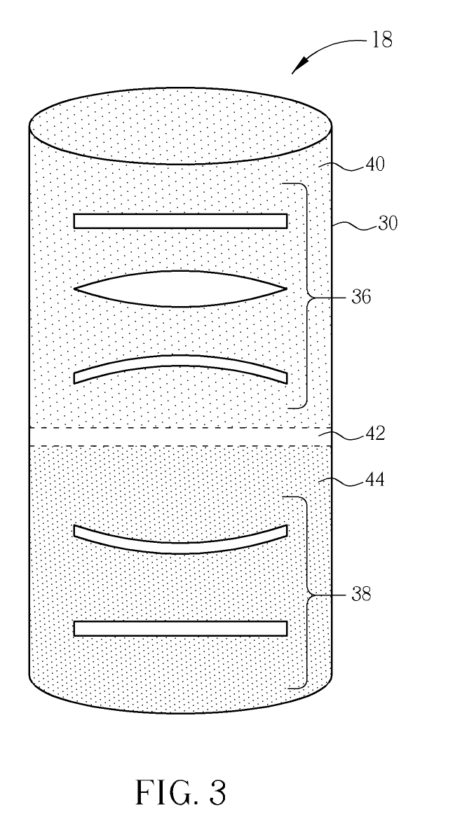

According to anther preferred embodiment of the present invention, the second lens module includes two sets of lenses immersed in different mediums respectively. FIG. 3 is a magnified localized view of the second lens module 18 in FIG. 1 according to a second embodiment of the present invention, wherein like reference numerals are used to refer to like elements throughout.

As shown in FIG. 3, the second lens module 18 includes a container 18, a liquid medium 40 in the container 18, a medium 44 in the container 18 which is adjacent to the liquid medium 40, a first set of lenses 36 immersed in the liquid medium 40 and a second set of the lenses 38 immersed in the medium 44. A glass 42 may be optionally disposed between the liquid medium 40 and the medium 44 to separate the liquid medium 40 and the medium 44.

The liquid medium 40 may be de-ionized water, a mixture of phosphoric acid (H₃PO₄) and water, a phosphoric acid solution, “Delphi”, which is available from Mitsui Chemical, oil (e.g., perfluorinated polyethers (PFPE)) or other liquids having a refractive index that is greater than 1.4 at a wavelength of 193 nm. The refractive index of the liquid medium 40 depends on the refractive indices of the whole lithography system including lenses, the photo resist, and other mediums. The refractive index of the liquid medium 40 can be any value which matches the refractive indices of the whole lithography system. Generally, the refractive index of the medium 40 is greater than 1.4 at a wavelength of 193 nm.

The medium 44 may be air. According to a preferred embodiment of the present invention the medium 44 may be preferably de-ionized water, a mixture of phosphoric acid (H₃PO₄) and water, a phosphoric acid solution, “Delphi”, which is available from Mitsui Chemical, oil (e.g., perfluorinated polyethers (PFPE)), supercritical fluid or other mediums having a refractive index that is greater than 1.4 at a wavelength of 193 nm. For instance, the first set of lenses 36 may be immersed in de-ionized water and the second set of lenses 38 may be immersed in mixture of phosphoric acid and water.

Although the above embodiments merely describe one and two medium to immerse one and two sets of lenses, respectively, other combinations of lenses and mediums can be used to implement the invention. For example, there may be three, four or more than four sets of lenses to be immersed in different kinds of mediums respectively. Taking three sets of lenses as an example, the three sets of lenses immersed in de-ionized water, a mixture of phosphoric acid, and Delphi, respectively, or the three sets of lenses immersed in de-ionized water, air, and a mixture of phosphoric acid and water, respectively, are considered to fall within the scope of the invention described and claimed herein. In addition, although only the second lens module 18 is described in the above embodiment, the lenses in the first lens module 14 can also utilize the same design used by the second lens module 18.

In particular, the resolution can be defined as: resolution=κλ/NA where κ is a lithographic constant, λ is an exposure radiation wavelength, and NA is a numerical aperture. Furthermore, the numerical aperture can be derived as follows: NA=n sin θ where n is a refractive index of the medium in which the lenses are working and 2θ is an angle of acceptance of a lens. Thus, the resolution can be increased by increasing the refractive index and/or decreasing the lithographic constant.

Therefore, the liquid medium 32, 40 of the first and second embodiment possess a refractive index greater than 1.4 at a wavelength of 193 nm, which increases the numerical aperture. If the medium 44 of the second embodiment also possesses a refractive index greater than 1.4 at a wavelength of 193 nm, the numerical aperture can be further increased. As the numerical aperture increases, the resolution is improved. Furthermore, for a traditional lens module, one skilled in the art should know that the complexity of the lenses is increased as the numerical aperture increases. However, compared to the traditional lens module, the lenses in the present invention require a less complex design to reach the same numerical aperture.

Moreover, the mediums 32, 40, 44 that immerse the lenses can be chosen depending on different designs. Usually, mediums that immerse the lenses may have refractive indices of greater than 1.4 at a wavelength of 193 nm. In fact, the lithography system includes many elements with different refractive indices; if the refractive indices of two adjacent elements are enormously different, total reflection may occur. The mediums in the present invention can also be a bridge to compromise the different refractive indices of the elements in the lithography system.

Those skilled in the art will readily observe that numerous modifications and alterations of the device and method may be made while retaining the teachings of the invention.

What is claimed is:

1. An optical module of a lithography system, comprising:
a container;
a liquid medium disposed within the container; and
a first set of lenses immersed in the liquid medium.

2. The optical module of claim 1 further comprising:
a medium situated adjacent to the liquid medium within the container; and
a second set of lenses immersed in the medium.

3. The optical module of claim 2, wherein the second medium is air.

4. The optical module of claim 2, wherein the second medium has a refractive index that is greater than 1.4 at a wavelength of 193 nm.

5. The optical module of claim 4, wherein the second medium is liquid.

6. The optical module of claim 2, wherein a glass is disposed between the first medium and the second medium.

7. The optical module of claim 1, wherein the liquid medium has a refractive index that is greater than 1.4 at a wavelength of 193 nm.

8. A lithography system, comprising:
a light source;
a photo mask positioned downstream of the light source;
an optical module having a front surface positioned downstream of the photo mask, comprising:
a container;
a liquid medium situated in the container; and
a first set of lenses immersed in the liquid medium;
a wafer stage positioned downstream of the optical module for supporting a wafer, comprising a dry film; and
a first medium positioned between the front surface of the optical module and a surface of the dry film.

9. The lithography system of claim 8, wherein the liquid medium has a refractive index that is greater than 1.4 at a wavelength of 193 nm.

10. The lithography system of claim 8, wherein the optical module further comprises:
a second medium situated adjacent to the liquid medium; and
a second set of lenses immersed in the second medium.

11. The lithography system of claim 10, wherein the second medium is air.

12. The lithography system of claim 10, wherein the second medium has a refractive index that is greater than 1.4 at a wavelength of 193 nm.

13. The lithography system of claim 12, wherein the second medium is liquid.

14. The lithography system of claim 10, wherein a glass is disposed between the liquid and the second medium.

15. The lithography system of claim 8, wherein the first medium has a refractive index that is greater than 1.4 at a wavelength of 193 nm.

16. The lithography system of claim 8, wherein the first medium is identical to the liquid medium.
